(19) United States
(12) Patent Application Publication
(10) Pub. No.: US 2011/0057318 A1
(43) Pub. Date: Mar. 10, 2011

(54) Die Package

(75) Inventors: Sung Chuan MA, Taoyuan County (TW); Tse Min Chu, Taoyuan County (TW)

(73) Assignee: MAO BANG ELECTRONIC CO., LTD., Taoyuan County (TW)

(21) Appl. No.: 12/354,348

(22) Filed: Jan. 15, 2009

(30) Foreign Application Priority Data
Feb. 5, 2008 (TW) 097202529

(51) Int. Cl. H01L 23/48

(52) U.S. Cl. 257/773; 257/E23.01

(57) ABSTRACT

A die is packaged. The package of the die has a line groove filled with a conductive material. A metal pad is exposed out of a solder mask. And the metal pad is connected with a die pad on the die through the line groove in a deflective way. In this way, a wiring space of a wafer is efficiently used; and a manufacturing yield of the wafer is enhanced.

### FIELD OF THE INVENTION

The present invention relates to packaging a die; more particularly, relates to obtaining a line with a metal pad connected with the die pad in a deflective way for efficiently using a wiring space of a wafer.

### DESCRIPTION OF THE RELATED ART

Generally, a solder mask is pasted on dies of a wafer through a method like stencil printing. Therein, sunken areas are vertically drilled on the dies to expose lines for electrical connections. Then, a film is pasted on dies of the wafer, where a window is left on sunken areas of the film for filling in a metal and exposed lines are thus fabricated. However, there is a certain error of alignment when the film is pasted on the dies. Hence, deviations are happened to the sunken areas, Furthermore, since the sunken areas are obtained through vertical drilling, the sunken areas occupy too much area of wiring space of the wafer and so the wafer is not used efficiently. Hence, the prior art does not fulfill all users' requests on actual use.

### SUMMARY OF THE INVENTION

The main purpose of the present invention is to package a die with a wiring space of a wafer efficiently used and a manufacturing yield enhanced.

To achieve the above purpose, the present invention is a die package, comprising a die, an insulator layer, a solder mask and a metal layer, where the die has a plurality of die pads; the insulator layer is covered on the die; the insulator layer has at least one line groove; the line groove is connected with the die pad; the solder mask is pasted on a surface of the insulator layer; the solder mask covers designated part of the insulator layer to obtain the line groove; the metal layer is obtained in the line groove until the die pad; the metal layer has a plurality of metal pads; and the metal pad is exposed in the solder mask and is electrically connected with the die pad. Accordingly, a novel die package is obtained,

### BRIEF DESCRIPTION OF THE DRAWING

The present invention will be better understood from the following detailed description of the preferred embodiment according to the present invention, taken in conjunction with the accompanying drawing, in which

FIG. 1 is the structural view showing the preferred embodiment according to the present invention.

### DESCRIPTION OF THE PREFERRED EMBODIMENT

The following description of the preferred embodiment is provided to understand the features and the structures of the present invention.

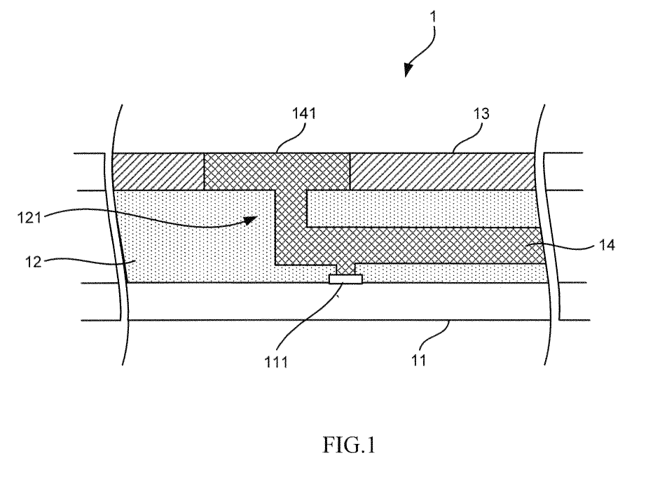

Please refer to FIG. 1, which is a structural view showing a preferred embodiment according to the present invention. As shown in the FIGURE, the present invention is a die package 1, comprising a die 11, an insulator layer 12, a solder mask 13 and a metal layer 14, where a wiring space of a wafer is efficiently used with an enhanced manufacturing yield.

The die 11 has a plurality of die pads 111.

The insulator layer 12 is covered on the die 11, where the insulator layer 12 has at least one line groove 121 and the line groove 121 is connected with the die pad 11.

The solder mask 13 is made of a high polymer resin, where the solder mask 13 is pasted on a surface of the insulator layer 12 and the solder mask 13 covers a designated part of the insulator layer 12 to obtain the line groove 121.

The metal layer 14 is formed in the line groove 121 until the die pad 111 and has a plurality of metal pads 141, where the metal pad 141 is exposed in the solder mask 13 and is electrically connected with the die pad 111.

Thus, with the above structure, a novel die package is obtained.

On using the present invention, a die 11 is obtained, where an insulator layer 12 is pasted on the die and a solder mask 13 is pasted on the insulator layer 12 through surface mount technology. On forming a line on the die 11, a pre-designed line groove 121 is formed in the insulator layer until the die 11 through photoimaging with a photoresist on the solder mask 13. Then, a conductive metal is filled in the line groove 121 through sputtering, chemical vapor deposition (CVD), sputtering together with electroplating, or CVD together with electroplating. Thus, a metal layer 14 and a plurality of metal pads 141 are formed, where the metal pad 141 is exposed in the solder mask 13 and is electrically connected with the die pad 111. Through the above processes, a die package 1 is assembled according to the present invention. Therein, by processing deposition through CVD for a longer time, a thicker metal layer 14 is obtained.

In this way, a line is formed according to the present invention, where the metal pad is connected with the die pad on the die in a deflective way. Hence, a wiring space of a wafer is efficiently used with an enhanced manufacturing yield.

To sum up, the present invention is a die package, where a line is formed with a metal pad connected with the die pad in a deflective way; and, thus, a wiring space of a wafer is efficiently used with an enhanced manufacturing yield.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A die package, comprising:
a die, said die having a plurality of die pads;
an insulator layer, said insulator layer being covered on said die, said insulator layer having at least one line groove, said line groove being connected with said die pad;
a solder mask, said solder mask being pasted on a surface of said insulator layer, said solder mask covering a designated part of said insulator layer to obtain said line groove; and
a metal layer, said metal layer being obtained in said line groove until said die pad, said metal layer having a plurality of metal pads, said metal pad being exposed in said solder mask and electrically connected with said die pad.

2. The package according to claim 1, wherein said solder mask is made of high polymer resin.

3. The package according to claim 1, wherein said solder mask is obtained through surface mount technology.

4. The package according to claim 1, wherein said metal layer is obtained through steps of: (a) photoimaging said line groove with a photoresist; and (b) filling said line groove with a conductive metal.

5. The package according to claim 4, wherein said conductive metal is filled in said line groove through a method selected from a group consisting of sputtering, chemical vapor deposition (CVD), sputtering together with electroplating, and CVD together with electroplating.
